(19) United States
(12) Patent Application Publication
(10) Pub. No.: US 2024/0327665 A1
(43) Pub. Date: Oct. 3, 2024

(54) PHOTOCURABLE COMPOSITION

(71) Applicant: CANON KABUSHIKI KAISHA, Tokyo (JP)

(72) Inventors: Fen WAN, Austin, TX (US); Weijun Liu, Cedar Park, TX (US)

(21) Appl. No.: 18/191,458

(22) Filed: Mar. 28, 2023

(51) Int. Cl. C09D 11/36; B41J 11/00; C09D 11/033; C09D 11/101; C09D 11/107

(52) U.S. Cl. CPC C09D 11/36; B41J 11/0021; C09D 11/033; C09D 11/101; C09D 11/107

(57) ABSTRACT

A photocurable composition can comprise a polymerizable material, an evaporative diluent, and a photoinitiator, wherein the polymerizable material can comprise at least one first polymerizable monomer having a boiling point at 1 atm of at least 250° C. in an amount of at least 80 wt %; the evaporative diluent can have a boiling point at 1 atm of not greater than 200° C.; an amount of the evaporative diluent can be at least 5 wt % and not greater than 40 wt %; a vapor pressure of the evaporative diluent can be at least five times greater than a vapor pressure of the at least one polymerizable monomer; a difference in a surface tension of the evaporative diluent to a surface tension of the photocurable composition can be not greater than 5 mN/m; and a viscosity of the photocurable composition may be not greater than 20 mPa·s.

### FIELD OF THE DISCLOSURE

The present disclosure relates to a photocurable composition, particularly to a photocurable composition adapted for forming photo-cured layers in the field of inkjet adaptive planarization (IAP).

### BACKGROUND

Inkjet Adaptive Planarization (IAP) is a process which planarizes a surface of a substrate, e.g., a wafer containing an electronic circuit, by jetting liquid drops of a curable composition on the surface of the substrate, and bringing a flat superstrate in direct contact with the added liquid to form a flat liquid layer. The flat liquid layer is typically solidified under UV light exposure, and after removal of the superstrate a planar surface is obtained which can be subjected to subsequent processing steps, for example baking, etching, and/or further deposition steps. There exists a need for improved photocurable compositions for IAP, which allow well controlled dispensing of the photocurable composition on a substrate, for making photo-cured layers with good strength, high etch resistance, and high thermal stability.

### SUMMARY

In one embodiment, a photocurable composition can comprise a polymerizable material, an evaporative diluent, and a photoinitiator, wherein the polymerizable material comprises at least one first polymerizable monomer having a boiling point at 1 atm of at least 250° C. in an amount of at least 80 wt % based on the total weight of the polymerizable material; the evaporative diluent has a boiling point at 1 atm of not greater than 200° C.; an amount of the evaporative diluent is at least 5 wt % and not greater than 40 wt % based on the total weight of the photocurable composition; a vapor pressure of the evaporative diluent is at least five times greater than a vapor pressure of the at least one polymerizable monomer; a difference in a surface tension of the evaporative diluent to a surface tension of the photocurable composition is not greater than 5 mN/m; and a viscosity of the photocurable composition is not greater than 20 mPa·s.

In one aspect of the photocurable composition, a contact angle of the photocurable composition to a fused silica template (CA-FS) can be at least 8 degrees and not greater than 30 degrees, and a contact angle of the photocurable composition to a primed silicon substrate (CA-SI) can be at least 2.0 degrees and not greater than 15 degrees, and the CA-FS may be at least 3 degrees greater than the CA-SI.

In another embodiment of the photocurable composition, the at least one first polymerizable monomer of the polymerizable material can include at least one mono-functional acrylate monomer, at least one multi-functional acrylate monomer, or a combination thereof.

In one aspect, the at least one first polymerizable monomer can include a multi-functional acrylate monomer. In a particular aspect, the at least one first polymerizable monomer may consist essentially of the at least one multi-functional acrylate monomer.

In another aspect, the at least one multi-functional acrylate monomer can include an aromatic multi-functional acrylate monomer.

In aspects, the at least one multi-functional acrylate monomer can include trimethylolpropane triacrylate (TMPTA); 9,9-bis[4-(2-acryloxy ethoxy) phenyl]fluorene (A-BPEF); neopentyl glycol diacrylate (A-NPG); diethylene glycol diacrylate; tricyclodecane dimethanol diacrylate (A-DCP); ethoxylated trimethylolpropane triacrylate; trimethylolpropane(PO)6 triacrylate; trimethylolpropane(EO)9 triacrylate; polyethylene glycol 600 diacrylate; trimethylolpropane(EO)15 triacrylate; pentaerythritol tetraacrylate; 1,3-adamantanediol diacrylate; dibenzyl-1,3 propane diacrylate; 1,8-naphthalenediyl diacrylate; 2,2-hexafluorobis(4-hydroxyphenyl)propane diacrylate; or any combination thereof.

In one embodiment of the photocurable composition, the evaporative diluent can include acetonitrile, propylene glycol methyl ether (PGME), cyclohexanone, n-hexyl acrylate (nHA), or any combination thereof. In a particular embodiment, the evaporative diluent may be acetonitrile.

In a certain aspect of the photocurable composition, the at least one multi-functional acrylate monomer can include trimethylolpropane triacrylate (TMPTA); 9,9-bis[4-(2-acryloxy ethoxy) phenyl]fluorene (A-BPEF); neopentyl glycol diacrylate (A-NPG), or any combination thereof and the evaporative diluent can include acetonitrile.

In a further embodiment of the photocurable composition, the difference in the surface tension of the evaporative diluent to the surface tension of the photocurable composition may be not greater than 3 mN/m.

In yet a further aspect of the photocurable composition, the viscosity of the photocurable composition may be not greater than 15 mPa·s.

In another aspect of the photocurable composition, the surface tension of the photocurable composition can be at least 28 mN/m and not greater than 35 mN/m.

In one aspect of the photocurable composition, the amount of the evaporative diluent can be at least 5 wt % and not greater than 30 wt % based on the total weight of the photocurable composition.

In yet another aspect of the photocurable composition, the amount of the polymerizable material can be at least 55 wt % based on a total weight of the photocurable composition. In a certain aspect, the amount of the polymerizable material may be at least 65 wt % based on a total weight of the photocurable composition.

In one embodiment, a laminate can comprise a substrate and a photo-cured layer overlying the substrate, wherein the photo-cured layer can be formed from the above-described photocurable composition.

In another embodiment, a method of manufacturing an article can comprise: applying a layer of a photocurable composition on a substrate, wherein the photocurable composition comprises a polymerizable material, an evaporative diluent, and a photoinitiator, wherein the polymerizable material comprises at least one first polymerizable monomer having a boiling point at 1 atm of at least 250° C. in an amount of at least 80 wt % based on the total weight of the polymerizable material, the evaporative diluent has a boiling point at 1 atm of not greater than 200° C., an amount of the evaporative diluent is at least 5 wt % and not greater than 40 wt % based on the total weight of the photocurable composition, a vapor pressure of the evaporative diluent is at least five times greater than a vapor pressure of the at least one polymerizable monomer; a difference in a surface tension of the evaporative diluent to a surface tension of the photocurable composition is not greater than 5 mN/m; and a viscosity of the photocurable composition is not greater than 20 mPa·s; bringing the photocurable composition into contact with a template or a superstrate; irradiating the photocurable composition with light to form a photo-cured layer; removing the template or the superstrate from the photo-cured layer; forming a pattern on the substrate; processing the substrate on which the pattern has been formed in the forming; and manufacturing the article from the substrate processed in the processing.

In one aspect of the method, the difference in the surface tension of the evaporative diluent to the surface tension of the photocurable composition may not be greater than 3 mN/m.

In another aspect of the method, the surface tension of the photocurable composition can be at least 28 mN/m and not greater than 35 mN/m.

### DETAILED DESCRIPTION

The following description is provided to assist in understanding the teachings disclosed herein and will focus on specific implementations and embodiments of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the imprint and lithography arts.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus.

As used herein, and unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

The present disclosure is directed to a photocurable composition comprising a polymerizable material, an evaporative diluent, and a photoinitiator, wherein the photocurable composition can include a combination of the following features: a) the polymerizable material can comprise at least one first polymerizable monomer having a boiling point at 1 atm of at least 250° C. in an amount of at least 80 wt % based on the total weight of the polymerizable material; b) the evaporative diluent can have a boiling point at 1 atm of not greater than 200° C.; c) an amount of the evaporative diluent can be at least 5 wt % and not greater than 40 wt % based on the total weight of the photocurable composition; d) a vapor pressure of the evaporative diluent can be at least five times greater than a vapor pressure of the at least one polymerizable monomer; e) a difference in a surface tension of the evaporative diluent to a surface tension of the photocurable composition can be not greater than 5 mN/m; and f) a viscosity of the photocurable composition may be not greater than 20 mPa·s.

The photocurable composition of the present disclosure can have a desired dispensing behavior suitable for IAP processing, while forming solid layers after photocuring having a high etch resistance and good mechanical strength. Two main properties which impact the fluid flow are the viscosity and the surface tension of a composition. It has been surprisingly found that the presence of a minor amount of a selected evaporative diluent can lower to a large extent the viscosity of a photocurable composition while having only a minor effect on the surface tension in comparison to the same composition which does not include the evaporative diluent. This makes it possible to modify photocurable compositions which are known of forming layers of high thermal stability and high etch resistance after curing, but have the disadvantage of a high viscosity. The addition of a minor amount of a selected evaporative solvent may lower the viscosity without making unwanted changes to the surface tension and thereby can make such photocurable compositions suitable for IAP processing.

As used herein, the term “evaporative diluent” means a solvent which lowers the viscosity of a photocurable composition to a high degree, while causing only a minor change of the surface tension of the photocurable composition.

The photocurable composition of the present disclosure can be designed that the forming of very fine pico-liter or smaller drop sizes is possible, and that after the placement of the droplets on a substrate and before merging of the droplets, the evaporative diluent can be evaporated from the photocurable composition such that less than 1% of volatile residues remain. This can insure a low shrinkage of the photo-cured layers desired in IAP processing during downstream heating steps.

In one aspect, the evaporative diluent can be a solvent which does not react with the monomers of the polymerizable material. In another aspect, the evaporative diluent can react with the polymerizable monomers and be integrated in the formed polymeric matrix.

The photocurable composition of the present disclosure can be designed that the viscosity can be not greater not greater than 20 mPa·s, not greater than 18 mPa·s, not greater than 15 mPa·s, not greater than 12 mPa·s, or not greater than 10 mPa·s. In another aspect, the viscosity may be at least 2 mPa·s, or at least 3 mPa·s, or at least 5 mPa·s. In a particular aspect, the viscosity may be not greater than 15 mPa·s. As used herein, all viscosity values relate to viscosities measured at a temperature of 23° C. with the Brookfield method using a Brookfield Viscometer.

In one embodiment, the amount of the evaporative diluent may be not greater than 40 wt % based on the total weight of the photocurable composition, such as not greater than 35 wt %, not greater than 30 wt %, not greater than 25 wt %, not greater than 20 wt %, or not greater than 15 wt %, or not greater than 12 wt %. In another aspect the amount of the evaporative diluent can be at least 5 wt %, or at least 8 wt %, or at least 10 wt %, or at least 12 wt %, or at least 15 wt %. In a certain aspect, the amount of the evaporative diluent can be at least 5 wt % and not greater than 15 wt % based on the total weight of the photocurable composition. The amount of the evaporative diluent can be a value between any of the maximum and minimum numbers noted above.

In one aspect, the presence of the evaporative diluent can cause a percentage viscosity decrease of at least 40%, or at least 50%, or at least 55%, or at least 60%, or at least 65%, wherein the percentage viscosity decrease is defined as the viscosity decrease in percent between the photocurable composition not including the evaporative diluent and the corresponding photocurable composition including the evaporative diluent.

In a further embodiment, the vapor pressure of the evaporative diluent can be at least 5 times greater than the vapor pressure of the polymerizable monomer with the highest vapor pressure of the polymerizable material, such as at least 7 times greater, at least 10 times greater, at least 20 times greater, at least 30 times greater, or at least 50 times greater.

In one aspect, the vapor pressure of the evaporative diluent can be at least 0.05 mmHg at 25° C., such as at least 0.1 mmHg, or at least 0.5 mmHg, or at least 1 mmHg, or at least 5 mmHg, or at least 10 mmHg, or at least 50 mmHg, or at least 80 mmHg. In other aspects, the vapor pressure may be not greater than 150 mmHg, or not greater than 130 mmHg, or not greater than 100 mmHg at 25° C.

In another aspect, the surface tension of the evaporative diluent can be at least 23 mN/m, or at least 25 mN/m, or at least 27 mN/m, or at least 30 mN/m. In a further aspect, the surface tension may be not greater than 40 mN/m, or not greater than 37 mN/m, or not greater than 35 mN/m, or not greater than 32 mN.

In a further aspect, the difference between the surface tension of the evaporative diluent and the surface tension of the photocurable composition may be not greater than 5 mN/m, or not greater than 4 mN/m, or not greater than 3 mN/m, or not greater than 2 mN/m.

In aspects, the evaporative diluent can include acetonitrile, propylene glycol methyl ether (PGME), cyclohexanone, n-hexyl acrylate (nHA), or any combination thereof. In a particular aspect, the evaporative diluent can include acetonitrile. In a certain particular aspect, the evaporative diluent can consist essentially of acetonitrile. As used herein, consisting essentially of acetonitrile means that at least 99 wt % or the evaporative diluent are acetonitrile.

The polymerizable material of the photocurable composition of the present disclosure can be designed for forming high-temperature stable layers with a high etch resistance. In one embodiment, the polymerizable material of the photocurable composition can include at least one first polymerizable monomer having a boiling point of at least 250° C. at 1 atm in an amount of at least 80 wt %.

In one aspect, the at least one first polymerizable monomer can include at least one mono-functional acrylate monomer, at least one multi-functional acrylate monomer, or a combination thereof. In a particular aspect the polymerizable material can include at least one multi-functional acrylate monomer. In a certain particular aspect, the at least one first polymerizable monomer can consist essentially of a multi-functional acrylate monomer. In another certain particular aspect, the multi-functional acrylate monomer can be an aromatic multi-functional acrylate monomer. As used herein, the phrase “at least one first polymerizable monomer consisting essentially of a multi-functional acrylate monomer” means that at least 99 wt % of the first polymerizable monomer are multi-functional acrylate monomers.

In another aspect, the at least one first polymerizable monomer can have a vapor pressure of not greater than 0.01 mmHg, or not greater than 0.005 mmHg, or not greater than 0.001 mmHg, or not greater than 0.0005 mmHg, or not greater than 0.0003 mmHg, at a temperature of 25° C.

Non-limiting examples of multi-functional acrylate monomers of the first polymerizable monomer can be bisphenol A dimethacrylate; m-xylylene diacrylate; neopentyl glycol diacrylate; trimethylolpropane triacrylate; tetramethylolmethane tetraacrylate; trimethylolpropane triacrylate (TMPTA); 9,9-bis[4-(2-acryloxy ethoxy) phenyl]fluorene (A-BPEF); neopentyl glycol diacrylate (A-NPG); diethylene glycol diacrylate; tricyclodecane dimethanol diacrylate; ethoxylated trimethylolpropane triacrylate; trimethylolpropane(EO)9 triacrylate; polyethylene glycol 600 diacrylate; trimethylolpropane(EO)15 triacrylate; pentaerythritol tetraacrylate; 1,3-adamantanediol diacrylate; dibenzyl-1,3 propane diacrylate; 1,8-naphthalenediyl diacrylate; or 2,2-hexafluorobis(4-hydroxyphenyl) propane diacrylate, or any combination thereof.

The polymerizable material can further comprise at least one second polymerizable monomer in an amount of up to 20 wt % based on the total weight of the polymerizable material, wherein the at least one second polymerizable monomer can have a boiling point below 250° C.

The at least one second monomer can be a mono-functional monomer or a multi-functional monomer. In a certain non-limiting examples, the at least second polymerizable monomer can be benzyl acrylate, divinylbenzene, trivinylbenzene, cyclohexyl acrylate, 2-methoxyethyl acrylate, tetrahydrofurfuryl acrylate, or 1H, 1H-heptafluorobutyl acrylate, 1,4-butanediol diacrylate.

In another aspect, the polymerizable material can also include one or more polymerizable oligomers or polymers as long as the viscosity requirements of the photocurable composition can be met.

In a particular aspect of the photocurable composition of the present disclosure, the at least one multi-functional acrylate monomer can include trimethylolpropane triacrylate (TMPTA); 9,9-bis[4-(2-acryloxy ethoxy) phenyl]fluorene (A-BPEF); neopentyl glycol diacrylate (A-NPG), or a combination thereof, and the evaporative diluent can include acetonitrile.

The amount of polymerizable material of the photocurable composition can be at least 30 wt % based on the total weight of the photocurable composition, such as at least 40 wt %, at least 50 wt %, or at least 60 wt %, or at least 70 wt %, or at least 80 wt %. In another aspect, the amount of polymerizable material may be not greater than 90 wt %, such as not greater than 85 wt %, or not greater than 80 wt %, or not greater than 70 wt %, or not greater than 60 wt %. The amount of the polymerizable material can be a value between any of the minimum and maximum values noted above. In a particular aspect, the amount of the polymerizable material can be at least 50 wt % and not greater than 85 wt % based on the total weight of the photocurable composition.

A further important aspect in IAP processing is that the contact angle of the photocurable composition to the template should be greater than the contact angle to the substrate. Furthermore, a low contact angle to the substrate is desired to help the spreading of the liquid resist composition. In one embodiment, the contact angle of the photocurable composition to a fused silica template (CA-FS) can be at least 3 degrees greater than the contact angle of the photocurable composition to a primed silicon substrate (CA-SI). In one aspect, the contact angle to the fused silica template (CA-FS) can be at least 8 degrees and not greater than 30 degrees, while the contact angle of the photocurable composition to the silicon substrate (CA-SI) may be at least 2.0 degrees and not greater than 15 degrees. As used herein, the term “primed silicon substrate” means a silicon substrate containing on the outer surface a vapor-deposited layer of acryloxymethyltrimethoxysilane.

The photocurable composition can be adapted that a photo-cured layer formed from the photocurable composition may have a high thermal stability. In one aspect, an onset temperature for the thermal degradation of the of the photo-cured layer may be greater than 250° C., or greater than 300° C., or greater than 350° C., or greater than 375° C., or greater than 400° C. As used herein, the onset thermal degradation temperature is also called “thermal degradation temperature,” and relates to the temperature in the TGA curve wherein a deflection of the curve from the almost linear plateau is first observed, shortly before the steep degradation decline of the sample.

In order to initiate the photo-curing of the photocurable composition if exposed to light, one or more photoinitiators can be included in the photocurable composition.

In a certain aspect, the curing can be also conducted by a combination of light and heat curing.

The photocurable composition can further contain one or more optional additives. Non-limiting examples of optional additives can be stabilizers, dispersants, solvents, surfactants, inhibitors, or any combination thereof.

The photocurable composition of the present disclosure can be adapted for use in inkjet adaptive planarization (IAP).

In one embodiment, the photocurable composition can be applied on a substrate to form a photo-cured layer. As used herein, the combination of substrate and photo-cured layer overlying the substrate is called a laminate.

The present disclosure is further directed to a method of forming a photo-cured layer. The method can comprise applying a layer of the photocurable composition described above over a substrate, bringing the photocurable composition into contact with a template or superstrate; irradiating the photocurable composition with light to form a photo-cured layer; and removing the template or the superstrate from the photo-cured layer.

The substrate and the solidified layer may be subjected to additional processing, for example, an etching process, to transfer an image into the substrate that corresponds to the pattern in one or both of the solidified layers and/or patterned layers that are underneath the solidified layer. The substrate can be further subjected to known steps and processes for device (article) fabrication, including, for example, curing, oxidation, layer formation, deposition, doping, planarization, etching, formable material removal, dicing, bonding, and packaging, and the like.

The photo-cured layer may be further used as an interlayer insulating film of a semiconductor device, such as LSI, system LSI, DRAM, SDRAM, RDRAM, or D-RDRAM, or as a resist film used in a semiconductor manufacturing process.

As further demonstrated in the examples, by inclusion of a minor amount of a suitable evaporative diluent, the viscosity of a photocurable composition can be lowered to a large extent while maintaining the surface tension to a high degree, which may allow improved dispersion of the photocurable composition and the forming of high quality layers suitable for IAP processing, such as high etch resistance and high thermal stability.

### EXAMPLES

The following non-limiting examples illustrate the concepts as described herein.

### Example 1

Table 1 includes a list of solvents known to be used in photocurable compositions. The solvents are organized by increasing boiling point (at 1 atm). Furthermore, Table 1 includes for each solvent the viscosity at 23° C., the vapor pressure, and the surface tension.

For the photocurable compositions of the present disclosure, as also shown in the examples below, from the solvents listed in Table 1 only acetonitrile (ACN), propylene glycol methyl ether (PGME), cyclohexanone, and nHA are suitable as evaporative diluents.

TABLE 1

| | Boiling | | Vapor | |
|---|---|---|---|---|
| Potential | Point | | Pressure | Surface |
| evaporative | [° C.] at | Viscosity | at 25° C. | Tension |
| diluents | 1 atm | [mPa · s] | [mmHg] | [mN/m] |
| Methanol | 65 | 0.5 | 127 | 22.7 |
| Tetrahydrofuran | 66 | 0.53 | 162 | 26.4 |
| Methyl acrylate | 80 | 0.5 | 87 | 28 |
| Acetonitrile | 82 | 0.4 | 89 | 31 |
| Isopropyl alcohol | 82.5 | 2.4 | 45.4 | 21.8 |
| (IPA) | | | | |
| Ethyl acrylate | 99 | 0.6 | 39 | 25 |
| Propylene glycol | 120 | 1.7 | 12.5 | 27.7 |
| methyl ether | | | | |
| (PGME) | | | | |
| Propylene glycol | 146 | 0.8 | 3.9 | 26.9 |
| methyl ether acetate | | | | |
| (PGMEA) | | | | |
| Cyclohexanone | 156 | 2.0 | 5.0 | 35 |
| N-Hexyl acrylate | 188 | 1.57 | 0.6 | 27.4 |
| (nHA) | | | | |
| Dimethylsulfoxide | 189 | 2 | 0.6 | 49.2 |
| (DMSO) | | | | |
| Trivinylcyclohexane | 202 | 1.3 | 0.6 | 26.9 |
| (TVCH) | | | | |
| N-vinylpyrrolidone | 218 | 2.48 | 0.1 | 40.2 |
| (NVP) | | | | |
| Benzyl acrylate | 229 | 2.2 | 0.07 | 36.2 |
| (BA) | | | | |

### Example 2

Photocurable compositions were prepared (C1 and S1) containing the polymerizable monomers 9,9-bis[4-(2-acryloxy ethoxy) phenyl]fluorene (A-BPEF) and benzyl acrylate (BA), two photoinitiators and one surfactant. The exact compositions can be seen in Table 2. The difference between C1 and S1 was the addition of 10 parts acetonitrile in sample S1. It can be seen that the addition of only 10 parts acetonitrile caused a strong decrease in the viscosity from 33 mPas to 11.9 mPa·s, while the surface tension maintained nearly at the same value.

TABLE 2

| Ingredient | Sample C1 | Sample S1 |
|---|---|---|
| A-BPEF | 40 | 40 |
| Benzyl acrylate (BA) | 60 | 60 |
| Acetonitrile | | 10 |
| Irgacure 651 | 2 | 2 |
| Irgacure 907 | 1 | 1 |
| FS2000M2 | 3 | 3 |
| Viscosity [mPa · s] | 33 | 11.9 |
| Surface Tension | 34.1 | 34.6 |
| [mN/m] | | |

### Example 3

Photocurable compositions were prepared (C2, S2 and S3) containing the polymerizable monomers tricyclodecane dimethanol diacrylate (A-DCP), dicyclopentenyl acrylate (DCPA), and isobornyl acrylate (IBXA), two photoinitiators and one surfactant. The exact compositions can be seen in Table 3. The difference between composition C2 and compositions S2 and S3 was the addition of acetonitrile, 10 parts in S2, and 20 parts in S3. It can be seen that the addition of only 10 parts acetonitrile caused a strong decrease in the viscosity from 26.1 mPa·s to 10.4 mPa·s (which corresponds to a viscosity decrease of 61.5%), while the surface tension maintained the same value. Adding 20 parts acetonitrile further lowered the viscosity to 8 mPa·s (viscosity decrease of about 70%), and the surface tension changed only to a minor extent, from 32.1 mN/m to 30.6 mN/m.

TABLE 3

| Ingredient | Sample C2 | Sample S2 | Sample S3 |
|---|---|---|---|
| A-DCP | 35 | 35 | 35 |
| DCPA | 35 | 35 | 35 |
| IBXA | 30 | 30 | 30 |
| Acetonitrile | | 10 | 20 |
| Irgacure 651 | 2 | 2 | 2 |
| Irgacure 907 | 1 | 1 | 1 |
| FS2000M2 | 3 | 3 | 3 |
| Viscosity [mPa · s] | 26.1 | 10.4 | 8 |
| Surface Tension | 32.1 | 32.1 | 30.6 |
| [mN/m] | | | |

### Example 4

Photocurable compositions were prepared (S4, C3, and C4) containing the polymerizable monomer neopentyl glycol diacrylate (A-NPG), an evaporative diluent, a photoinitiator and a surfactant. The exact compositions are summarized in Table 4. The compositions differed by varying the type of the evaporative diluent, using acetonitrile (surface tension 31 mN/m) in composition S4, DMSO (surface tension 49.2 mN/m) in composition C3, and IPA (surface tension 21.8 mN/m) in composition C4.

Although all compositions had a low viscosity in the range of 2-6 mPa·s, the measurements of the contact angle towards the surface of a fused-silica material (to simulate the template), and towards the surface of a primed silicon material (to simulate the substrate) showed very different properties between the three compositions.

Only composition S4 formed contact angles such that the contact angle towards the template is at least 3 degrees greater than the contact angle towards the substrate, and that a minimum contact angle towards the substrate is at least 2, as desired in IAP processing.

It can be further seen from the data summarized in Table 4 that including DMSO, which has a surface tension of 49.2 mN/m caused a much higher surface tension of the final composition C3 of 41 mN/m in comparison to composition S4 having a surface tension of 31 mN/m, which contained acetonitrile.

TABLE 4

| Ingredient | Sample S4 | Sample C3 | Sample C4 |
|---|---|---|---|
| SR247 | 70 | 70 | 70 |
| Acetonitrile | 30 | | |
| DMSO | | 30 | |
| Isopropyl alcohol | | | 30 |
| Irgacure 907 | 2 | 2 | 2 |
| FS2000M2 | 1 | 1 | 1 |
| Viscosity [mPa · s] | 1.84 | 5.53 | 3.62 |
| Surface Tension | 31.2 | 41.2 | 25.6 |
| [mN/m] | | | |
| CA on template | 8.8 | 7.2 | 9.1 |
| [degrees] | | | |
| CA on substrate | 2.8 | 7.1 | 0 |
| [degrees] | | | |

The data in Table 4 further demonstrate that samples C3 and C4 are not suitable for IAP processing. If the contact angle to the template and to the substrate is very similar, like in sample C3, it can lead to an undesirable imprinting performance. Furthermore, if the contact angle towards the substrate is very low (below 2 degrees), it can cause extrusion problems.

### Example 5

### Measurement of Evaporation Rate

Evaporation experiments were conducted comparing the evaporation rate of samples C1 and S1 (of Example 2) and C2, S2, and S3 (of Example 3).

Each test was conducted by coating a first glass slide with an adhesion promoter and weighing the first glass slide. Thereafter, on a second glass slide (not containing an adhesion promoter coating) three drops of the photocurable composition to be tested (herein also called “test composition”) were added, such that the initial weight of the test composition added to the second glass slide was 0.033 g. After placing the three drops on the second glass slide, the second glass slide was immediately covered with the first glass slide. After the test composition was well spread, the first glass slide was separated again from the second glass slide, and a thin layer of the test composition remained on the first glass slide, which evaporation rate was measured.

For measuring the evaporation rate, the weight loss of the first glass slide containing a layer of the test composition was measured after a first time period of 5 minutes (T1), and after a second time period of 30 minutes (T2).

TABLE 5

| | Initial | | Weight | Weight | | Weight | Weight |
|---|---|---|---|---|---|---|---|
| | Weight | T1 | Loss T1 | Loss T1 | T2 | Loss T1 | Loss T1 |
| Sample | [mg] | [min] | [mg] | [%] | [min] | [mg] | [%] |
| C1 | 37.4 | 5 | 0.4 | 1.1 | 30 | 0.6 | 1.6 |
| S1 | 82.6 | 5 | 4.7 | 5.7 | 10 | 5.0 | 6.1 |
| C2 | 33.6 | 5 | n.d. | n.d. | 10 | n.d. | n.d. |
| S2 | 57.2 | 5 | 6.3 | 11.0 | 10 | 6.3 | 11.0 |
| S3 | 62.5 | 5 | 3.8 | 6.1 | 10 | 3.8 | 6.1 |

The data in Table 5 demonstrate that the representative samples S1, S2, and S3 of the present disclosure had a much higher weight loss than comparative samples C1 and C2. This weight loss is desired in the photocurable compositions and relates to the evaporation of the added evaporative diluent. In an actual IAP process, since the size of the droplets is in a pico-liter size range, the evaporative diluent is expected to evaporate very quickly, before the droplets are merging together. A fast evaporation can be concluded especially from samples S5 and S6, wherein no difference could be found by extending the time from 5 minutes to 10 minutes.

### Measurement of the Viscosities

The viscosities for samples C1-C4 and S16-S18 were measured with a Brookfield DV-11+Pro viscometer using spindle #18. For each viscosity measurement, a sample of 6-7 ml was taken, added to the sample chamber, and allowed to equilibrate for 15-20 minutes to reach the target temperature of 23° C. The viscosities were measured with spindle #18 at a speed of 135 rpm. For each sample, the measurement was three times repeated and an average value calculated.

### Measurement of Surface Tension

The surface tension of the compositions was measured by Pendant Drop method by using a DM-701 Contact Angle Meter made by Kyowa Interface Science Co. Ltd. (Japan). For the measurement, a syringe containing the liquid test composition was loaded on the syringe holder of DM-701 and the Pendant Drop measuring program of the control panel was started. The DM-701 allows for automatic liquid dispensing and drop size control. The drop images were captured and the drop shapes were analyzed by using the Young-Laplace theory by the software. For the binary system, the surface tension of the mixture can be calculated by the sum of the product of the surface tension and mole fraction for each component.

### Measurement of Contact Angle

The contact angle (CA) was measured with a Drop Master DM-701 contact angle meter made by Kyowa Interface Science Co. Ltd. (Japan).

For the testing of the contact angle to a fused-silica template (CA-FS), a fused silica slide was used to mimic the template surface during real imprinting process.

For measuring the contact angle to a silicon substrate (CA-SI), a primed silicon wafer was used containing a vapor-deposited silane layer (acryloxymethyltrimethoxysilane) as adhesion promoter to mimic the substrate surface during real imprinting process (“CA on substrate”).

The actual contact angle measurement was started by adding 2 ml of the test sample to the syringe, of which 2 μl sample per test was added by the machine to the target surface. Drop images were continuously captured by a CCD camera from the time the sample drop touched the surface. The contact angle was automatically calculated by the software based on the analysis of the images.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A photocurable composition comprising a polymerizable material, an evaporative diluent, and a photoinitiator, wherein
the polymerizable material comprises at least one first polymerizable monomer having a boiling point at 1 atm of at least 250° C. in an amount of at least 80 wt % based on the total weight of the polymerizable material;
the evaporative diluent has a boiling point at 1 atm of not greater than 200° C.;
an amount of the evaporative diluent is at least 5 wt % and not greater than 40 wt % based on the total weight of the photocurable composition;
a vapor pressure of the evaporative diluent is at least five times greater than a vapor pressure of the at least one polymerizable monomer;
a difference in a surface tension of the evaporative diluent to a surface tension of the photocurable composition is not greater than 5 mN/m; and
a viscosity of the photocurable composition is not greater than 20 mPa·s.

2. The photocurable composition of claim 1, wherein a contact angle of the photocurable composition to a fused silica template (CA-FS) is at least 8 degrees and not greater than 30 degrees, and a contact angle of the photocurable composition to a primed silicon substrate (CA-SI) is at least 2.0 degrees and not greater than 15 degrees, and the CA-FS is at least 3 degrees greater than the CA-SI.

3. The photocurable composition of claim 1, wherein the at least one first polymerizable monomer includes at least one mono-functional acrylate monomer, at least one multi-functional acrylate monomer, or a combination thereof.

4. The photocurable composition of claim 3, wherein the at least one first polymerizable monomer includes a multi-functional acrylate monomer.

5. The photocurable composition of claim 4, wherein the at least one first polymerizable monomer consists essentially of the at least one multi-functional acrylate monomer.

6. The photocurable composition of claim 3, wherein the at least one multi-functional acrylate monomer includes an aromatic multi-functional acrylate monomer.

7. The photocurable composition of claim 3, wherein the at least one multi-functional acrylate monomer includes trimethylolpropane triacrylate; 9,9-bis[4-(2-acryloxy ethoxy) phenyl]fluorene; neopentyl glycol diacrylate; diethylene glycol diacrylate; tricyclodecane dimethanol diacrylate; ethoxylated trimethylolpropane triacrylate; trimethylolpropane(PO)6 triacrylate; trimethylolpropane(EO)9 triacrylate; polyethylene glycol 600 diacrylate; trimethylolpropane(EO)15 triacrylate; pentaerythritol tetraacrylate; 1,3-adamantanediol diacrylate, dibenzyl-1,3 propane diacrylate, 1,8-naphthalenediyl diacrylate, or 2,2-hexafluoro bis(4-hydroxyphenyl)propane diacrylate, or any combination thereof.

8. The photocurable composition of claim 1, wherein the evaporative diluent includes acetonitrile, propylene glycol methyl ether, cyclohexanone, n-hexyl acrylate, or any combination thereof.

9. The photocurable composition of claim 8, wherein the evaporative diluent includes acetonitrile.

10. The photocurable composition of claim 7, wherein the at least one multi-functional acrylate monomer includes trimethylolpropane triacrylate; 9,9-bis[4-(2-acryloxy ethoxy) phenyl]fluorene; neopentyl glycol diacrylate, or a combination thereof and the evaporative diluent includes acetonitrile.

11. The photocurable composition of claim 1, wherein the difference in the surface tension of the evaporative diluent to the surface tension of the photocurable composition is not greater than 3 mN/m.

12. The photocurable composition of claim 1, wherein the viscosity of the photocurable composition is not greater than 15 mPa·s.

13. The photocurable composition of claim 1, wherein the surface tension of the photocurable composition is at least 28 mN/m and not greater than 35 mN/m.

14. The photocurable composition of claim 1, wherein the amount of the evaporative diluent is at least 5 wt % and not greater than 30 wt % based on the total weight of the photocurable composition.

15. The photocurable composition of claim 1, wherein the amount of the polymerizable material is at least 55 wt % based on a total weight of the photocurable composition.

16. The photocurable composition of claim 1, wherein the amount of the polymerizable material is at least 65 wt % based on a total weight of the photocurable composition.

17. A laminate comprising a substrate and a photo-cured layer overlying the substrate, wherein the photo-cured layer is formed from the photocurable composition of claim 1.

18. A method of manufacturing an article, comprising:
applying a layer of a photocurable composition on a substrate, wherein the photocurable composition comprises a polymerizable material, an evaporative diluent, and a photoinitiator, wherein
the polymerizable material comprises at least one first polymerizable monomer having a boiling point at 1 atm of at least 250° C. in an amount of at least 80 wt % based on the total weight of the polymerizable material;
the evaporative diluent has a boiling point at 1 atm of not greater than 200° C.;
an amount of the evaporative diluent is at least 5 wt % and not greater than 40 wt % based on the total weight of the photocurable composition;
a vapor pressure of the evaporative diluent is at least five times greater than a vapor pressure of the at least one polymerizable monomer;
a difference in a surface tension of the evaporative diluent to a surface tension of the photocurable composition is not greater than 5 mN/m; and
a viscosity of the photocurable composition is not greater than 20 mPa·s;
bringing the photocurable composition into contact with a template or a superstrate;
irradiating the photocurable composition with light to form a photo-cured layer;
removing the template or the superstrate from the photo-cured layer;
forming a pattern on the substrate;
processing the substrate on which the pattern has been formed in the forming; and
manufacturing the article from the substrate processed in the processing.

19. The method of claim 18, wherein the difference in the surface tension of the evaporative diluent to the surface tension of the photocurable composition is not greater than 3 mN/m.

20. The photocurable composition of claim 1, wherein the surface tension of the photocurable composition is at least 28 mN/m and not greater than 35 mN/m.
